(19) United States
(12) Patent Application Publication
(10) Pub. No.: US 2013/0292846 A1
(43) Pub. Date: Nov. 7, 2013

(54) SEMICONDUCTOR PACKAGE

(71) Applicant: SAMSUNG ELECTRONICS CO., LTD., Suwon-si (KR)

(72) Inventors: Seok-hyun Lee, Hwaseong-si (KR); Sun-won Kang, Seongnam-si (KR); Ho-geon Song, Suwon-si (KR)

(73) Assignee: SAMSUNG ELECTRONICS CO., LTD., Suwon-si (KR)

(21) Appl. No.: 13/768,649

(22) Filed: Feb. 15, 2013

(30) Foreign Application Priority Data
May 7, 2012 (KR) 10-2012-0048317

(51) Int. Cl. H01L 23/538

(52) U.S. Cl. CPC H01L 23/538; H01L 23/5384
USPC 257/774; 257/778

(57) ABSTRACT

Provided is a semiconductor package including a first semiconductor chip and a second semiconductor chip respectively disposed at a bottom and at a top so that active surfaces thereof face each other. Further includes is a first molding member for sealing the first semiconductor chip and exposing the active surface of the first semiconductor chip through a top surface, a first rewiring formed on the top surface of the first molding member and the active surface of the first semiconductor chip, a second rewiring formed on a bottom surface of the first molding member, a through-via for penetrating through the first molding member and electrically connecting the first and second rewirings, and a first connection member disposed between the first and second semiconductor chips. Also provided are various systems including same and various methods for making same.

### CROSS-REFERENCE TO RELATED APPLICATIONS

This application claims the benefit of Korean Patent Application No. 10-2012-0048317, filed on May 7, 2012, in the Korean Intellectual Property Office, the disclosure of which is incorporated herein in its entirety by reference.

### FIELD OF INVENTION

The inventive concept relates to a semiconductor package, and more particularly, to a semiconductor package having a face-to-face structure.

### BACKGROUND

Although the overall size of electronic products has considerably decreased, the electronic products are required to have large and fast data processing capacities. Accordingly, the integration of semiconductor devices used in electronic products needs to be increased, and thus, methods of stacking a plurality of semiconductor chips have been suggested. However, when a plurality of semiconductor chips are stacked to increase the integration thereof, an effective operation speed may deteriorate due to an increase in a distance between the semiconductor chips and, thus, it may be difficult to increase the integration of a semiconductor package.

With regard to high density devices, when chips are stacked in one package so as to increase the density, package loading is increased, thereby leading to deterioration of an effective operation speed of the package. Also, although a stack package is characterized in that semiconductor chips in one semiconductor package have different capacities and sizes, it is difficult to fabricate a package including chips of similar sizes and/or type, and in this case, a wire loop height is increased, thereby generating wire sweeping.

### SUMMARY

The inventive concept provides a semiconductor package having an improved operation speed and high integration, and a method of making same.

According to an aspect of the inventive concept, there is provided a semiconductor package including: a first semiconductor chip and a second semiconductor chip respectively disposed at a bottom and at a top so that active surfaces thereof face each other; a first molding member for sealing the first semiconductor chip and exposing the active surface of the first semiconductor chip through a top surface; a first rewiring formed on the top surface of the first molding member and the active surface of the first semiconductor chip; a second rewiring formed on a bottom surface of the first molding member; a through-via penetrating through the first molding member and electrically connecting the first and second rewirings; and a first connection member disposed between the first and second semiconductor chips.

In various embodiments, the top surface of the first molding member and the active surface of the first semiconductor chip may be at the same level.

In various embodiments, the semiconductor package may further include a second connection member formed on the second rewiring to be electrically connected to an external device.

In various embodiments, the first semiconductor chip may be a master chip and the second semiconductor chip may be a slave chip.

In various embodiments, the semiconductor package may further include a second molding member for sealing the second semiconductor chip and exposing the active surface of the second semiconductor chip.

In various embodiments, a bottom surface of the second molding member and the active surface of the second semiconductor chip may be at the same level.

In various embodiments, the semiconductor package may further include a third rewiring formed on a bottom surface of the second molding member and the active surface of the second semiconductor chip.

In various embodiments, the first connection member may electrically connect the first and third rewirings.

In various embodiments, the through-via may be spaced apart from the first semiconductor chip.

In various embodiments, the first connection member may be disposed between the active surface of the second semiconductor chip and the first rewiring.

In various embodiments, the semiconductor package may further include an underfill member formed between the first rewiring and the active surface of the second semiconductor chip.

According to another aspect of the inventive concept, there is provided a semiconductor package including: a first semiconductor chip and a second semiconductor chip respectively disposed at a top and at a bottom so that active surfaces thereof face each other; a first molding member for sealing the first semiconductor chip and exposing the active surface of the first semiconductor chip through a bottom surface; a rewiring formed on the bottom surface of the first molding member and the active surface of the first semiconductor chip; and a first connection member disposed between the first and second semiconductor chips.

In various embodiments, the active surface of the first semiconductor chip and the bottom surface of the first molding member may be at the same level.

In various embodiments, the semiconductor package may further include a second connection member formed on the rewiring to be electrically connected to an external device, wherein the second connection member may be disposed to surround the second semiconductor chip.

In various embodiments, the first connection member may be disposed between the rewiring and the active surface of the second semiconductor chip.

According to another aspect of the invention, provided is an electronic system, comprising: a controller comprising a processor to control the system; an interface configured as a data transmission path between the system and an external device; and a memory. The memory comprising a semiconductor package, comprising: a first semiconductor chip and a second semiconductor chip respectively disposed at a top and at a bottom so that active surfaces thereof face each other; a first molding member for sealing the first semiconductor chip and exposing the active surface of the first semiconductor chip through a bottom surface; a rewiring formed on the bottom surface of the first molding member and the active surface of the first semiconductor chip; and a first connection member disposed between the first and second semiconductor chips.

In various embodiments, the system may further comprise an input/output device configured to exchange data with a user.

In various embodiments, the system may include a cellular telephone.

In various embodiments, the active surface of the first semiconductor chip and the bottom surface of the first molding member may be at the same level.

In various embodiments, the semiconductor package may further comprise a second connection member formed on the rewiring to be electrically connected to the external device, wherein the second connection member is disposed to surround the second semiconductor chip.

### BRIEF DESCRIPTION OF THE DRAWINGS

Exemplary embodiments of the inventive concept will be more clearly understood from the following detailed description taken in conjunction with the accompanying drawings in which:

FIG. 1 is a cross-sectional view of an embodiment of a semiconductor package, according to aspects of the inventive concept;

FIG. 2 is a diagram showing an embodiment of an electric path in the semiconductor package of FIG. 1, according to aspects of the inventive concept;

FIG. 3 is a cross-sectional view of another embodiment of a semiconductor package, according to aspects of the inventive concept;

FIG. 4 is a cross-sectional view of another embodiment of a semiconductor package, according to aspects of the inventive concept;

FIG. 5 is a cross-sectional view of another embodiment of a semiconductor package, according to aspects of the inventive concept;

FIG. 6 is a cross-sectional view of another embodiment of a semiconductor package, according to aspects of the inventive concept;

FIG. 7 is a cross-sectional view of another embodiment of a semiconductor package, according to aspects of the inventive concept;

FIG. 8 is a cross-sectional view of another embodiment of a semiconductor package, according aspects of the inventive concept;

FIGS. 9 through 19 are cross-sectional views for describing an embodiment of a method of manufacturing a semiconductor package, according to aspects of the inventive concept;

FIG. 20 is a schematic diagram of an embodiment of a system, according to aspects of the inventive concept; and

FIG. 21 is a perspective view of an embodiment of an electronic device comprising a semiconductor package according to aspects of the inventive concept is applicable.

### DETAILED DESCRIPTION OF THE EMBODIMENTS

Hereinafter, aspects of the inventive concept will be described more fully with reference to the accompanying drawings, in which exemplary embodiments of the inventive concept are shown. This inventive concept may, however, be embodied in many different forms and should not be construed as limited to the exemplary embodiments set forth herein. In the drawings, like reference numerals in the drawings denote like elements.

It will be understood that, although the terms ‘first’, ‘second’, ‘third’, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept. For example, a first element may be designated as a second element, and similarly, a second element may be designated as a first element without departing from the teachings of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, the term “and/or” includes any and all combinations of one or more of the associated listed items. Expressions such as “at least one of,” when preceding a list of elements, modify the entire list of elements and do not modify the individual elements of the list.

If an embodiment is differently realizable, a specified operation order may be differently performed from a described order, as constituting further embodiments. For example, two consecutive operations may be substantially simultaneously performed, or in an order opposite to the described order, in some embodiments.

Variations from the shapes of the illustrations as a result, for example, of manufacturing techniques and/or tolerances, are to be expected. Thus, embodiments of the inventive concept should not be construed as limited to the particular shapes of regions illustrated herein, but may include deviations in shapes that result, for example, from manufacturing.

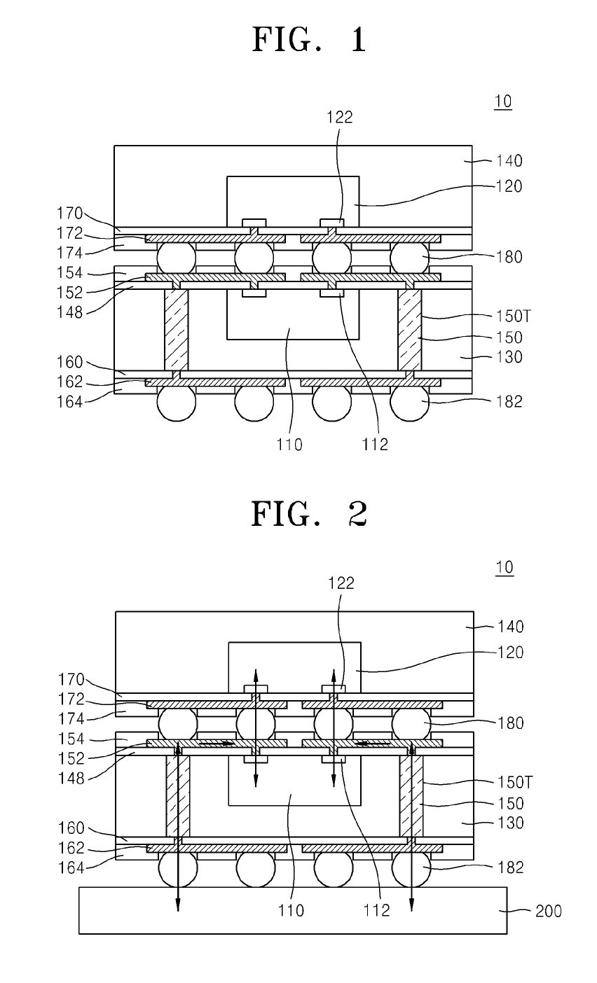

FIG. 1 is a cross-sectional view of an embodiment of a semiconductor package 10 according to aspects of the inventive concept.

Referring to FIG. 1, the semiconductor package 10 includes a first semiconductor chip 110 and a second semiconductor chip 120, respectively, disposed at a bottom and at a top so that active surfaces thereof face each other. The semiconductor package 10 further includes a first connection member 180 electrically connecting the first and second semiconductor chips 110 and 120, a first molding member 130 for sealing the first semiconductor chip 110 and exposing the active surface of the first semiconductor chip 110 through a top surface, and a second molding member 140 sealing the second semiconductor chip 120 and exposing the active surface of the second semiconductor chip 120 through a bottom surface.

A top surface of the first semiconductor chip 110 is the active surface and a bottom surface of the first semiconductor chip 110 is an inactive surface. The first semiconductor chip 110 may include an integrated circuit (IC). The active surface of the first semiconductor chip 110 includes at least one pad 112 connected to the IC. The pad 112 may include at least one material selected from among aluminum (Al), copper (Cu), silver (Ag), gold (Au), and palladium (Pd).

The first semiconductor chip 110 may be a memory chip, as an example. Examples of the memory chip may include various types of memory circuits, such as dynamic random access memory (DRAM), static RAM (SRAM), a flash memory, a phase-change RAM (PRAM), a resistive RAM (ReRAM), a ferroelectric RAM (FeRAM), and a magnetic RAM (MRAM). The first semiconductor chip 110 may operate as a master chip that transmits and receives data by communicating with a memory controller, or that receives various control signals and a voltage signal from the memory controller.

The first molding member 130 seals the first semiconductor chip 110 and exposes an active surface of the first semiconductor chip 110 through the top surface. The top surface of the first molding member 130 may be at the same level as the active surface of the first semiconductor chip 110. In various embodiments, the first molding member 130 may include an insulation resin, such as an epoxy molding compound, as an example.

A through-via 150 is formed in the first molding member 130. The through-via 150 may be formed by filling a conductive material in a through-hole 150T in the first molding member 130. The through-via 150 may be spaced apart from the first semiconductor chip 110 by a predetermined interval.

A first rewiring 152 is formed on the active surface of the first semiconductor chip 110, the top surface of the through-via 150, and the top surface of the first molding member 130. In other words, a first insulation layer 148 exposing a top surface of the pad 112 of the first semiconductor chip 110 and a top surface of the through-via 150, the first rewiring 152 electrically connecting the pad 112 and the through-via 150 on the first insulation layer 148, and a first solder resist layer 154 exposing a predetermined region of the first rewiring 152 on the first insulation layer 148 are formed.

A second rewiring 162 is formed on bottom surfaces of the first molding member 130 and through-via 150. In other words, a second insulation layer 160 exposing a bottom of the through-via 150, the second rewiring 162 electrically connected to the through-via 150 on the second insulation layer 160, and a second solder resist layer 164 exposing a predetermined region of the second rewiring 162 on the second insulation layer 160 are formed.

The first and second rewirings 152 and 162 may be electrically connected to each other through the through-via 150.

The first rewiring 152 is electrically connected to the pad 112 of the first semiconductor chip 110, the through-via 150, and the first connection member 180. The first rewiring 152 may include at least one material selected from among aluminum (Al), copper (Cu), tin (Sn), nickel (Ni), gold (Au), platinum (Pt), and an alloy thereof, and may be a multilayer in which Cu, Au, and Ni are sequentially stacked.

A second connection member 182 electrically connecting the semiconductor package 10 to an external device is formed on a bottom surface of the second rewiring 162, and the second rewiring 162 is electrically connected to the through-via 150 and the second connection member 182. The second rewiring 162 may include at least one material selected from among Al, Cu, Sn, Ni, Au, Pt, and an alloy thereof, and may be a multilayer in which Cu, Au, and Ni are sequentially stacked.

The active surface of the second semiconductor chip 120 may be disposed to face the active surface of the first semiconductor chip 110. In other words, the second semiconductor chip 120 is disposed such that the active surface is a bottom surface and an inactive surface is a top surface. The second semiconductor chip 120 may include an IC therein. The active surface of the second semiconductor chip 120 includes at least one pad 122 connected to the IC. The pad 122 includes at least one material selected from among Al, Cu, Ag, Au, and Pd.

The second semiconductor chip 120 may be a memory chip. Examples of the memory chip may include various types of memory circuits, such as DRAM, SRAM, a flash memory, a PRAM, a ReRAM, a FeRAM, and an MRAM.

The second semiconductor chip 120 may operate as a slave chip that provides read data to the first semiconductor chip 110 in response to various control signals or records data from the master chip, for example, the first semiconductor chip 110.

The second molding member 140 seals the second semiconductor chip 120 and exposes the active surface of the second semiconductor chip 120 through the bottom surface. The bottom surface of the second molding member 140 may be at the same level with the active surface of the second semiconductor chip 120. The second molding member 140 may include an insulation resin, for example, an epoxy molding compound.

A third rewiring 172 is formed on the active surface of the second semiconductor chip 120 and the bottom surface of the second molding member 140. In other words, a third insulation layer 170 exposing the pad 122 of the second semiconductor chip 120, the third rewiring 172 electrically connected to the pad 122 on the third insulation layer 170, and a third solder resist layer 174 exposing a predetermined region of the third rewiring 172 on the third insulation layer 170 are formed.

The third rewiring 172 is electrically connected to the pad 122 of the second semiconductor chip 120 and the first connection member 180. The third rewiring 172 may include at least one material selected from among Al, Cu, Sn, Ni, Au, Pt, and an alloy thereof, and may be a multilayer in which Cu, Au, and Ni are sequentially stacked.

In the semiconductor package 10 according to the current embodiment, since the active surfaces of the first and second semiconductor chips 110 and 120 face each other and a substrate is not used therebetween, a physical distance between the first and second semiconductor chips 110 and 120 may be reduced. Accordingly, when the first semiconductor chip 110 operates as a master chip and the second semiconductor chip 120 operates as a slave chip, an operation distance between the first and second semiconductor chips 110 and 120 is reduced. Thus, not only an operation speed of the semiconductor package 10 is improved, but also integration of the semiconductor package 10 is increased.

FIG. 2 is a diagram showing an embodiment of an electric path in the semiconductor package 10 of FIG. 1, according to aspects of the inventive concept.

Referring to FIG. 2, the semiconductor package 10 may be electrically connected to an external device 200, such as, for example, a printed circuit board, through the second connection member 182.

The semiconductor package 10 may transmit/receive signals to/from the external device 200 through the second connection member 182. A signal received by the second connection member 182 from the external device 200 may be transmitted to the first semiconductor chip 110 through the second rewiring 162, the through-via 150, the first rewiring 152, and the pad 112. Since the active surfaces of the first and second semiconductor chips 110 and 120 face each other, and the first and third rewirings 152 and 172 formed on the active surfaces of the first and second semiconductor chips 110 and 120 are connected to each other by the first connection member 180, a mutual connection between the master chip and the slave chip may be short, and deterioration of electric characteristics of the semiconductor package 10 due to a long distance between the master and slave chips may be prevented.

In other words, the first semiconductor chip 110 may quickly transmit a signal received from the external device 200 to the second semiconductor chip 120 through the first connection member 180, the third rewiring 172, and the pad 122. And the second semiconductor chip 120, as a slave chip, may quickly respond to an operation command of the first semiconductor chip 110.

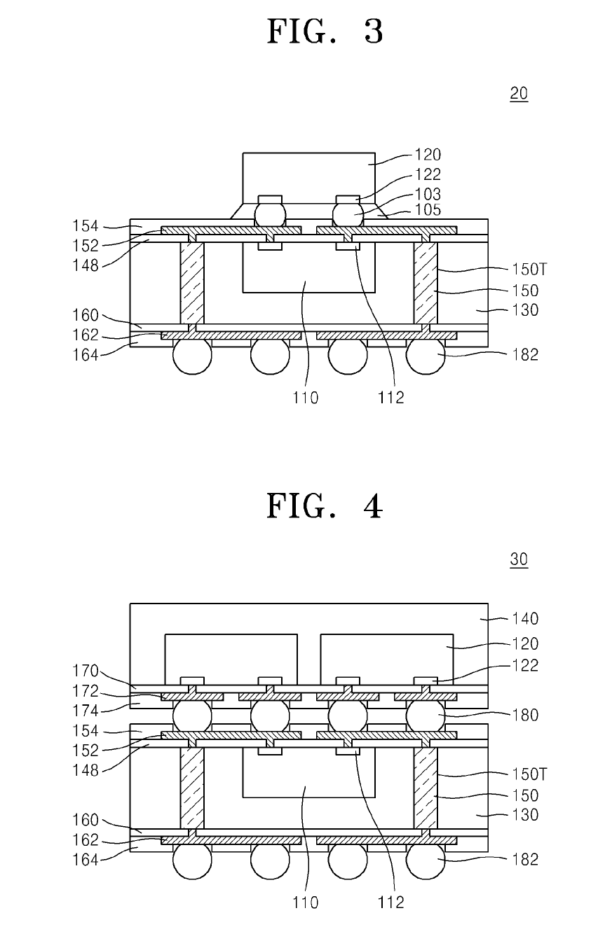

FIG. 3 is a cross-sectional view of another embodiment of a semiconductor package 20 according to aspects of the inventive concept. In FIG. 3, the same reference numerals as in FIG. 1 denote the same elements, and details thereof are not repeated.

Referring to FIG. 3, the semiconductor package 20 includes the second semiconductor chip 120 having the active surface facing the active surface of the first semiconductor chip 110. The second semiconductor chip 120 may be disposed on the first rewiring 152 in a flip-chip bonding manner so that the active surface of the second semiconductor chip 120 faces the active surface of the first semiconductor chip 110.

An underfill member 105 may be disposed between the first rewiring 152 and the second semiconductor chip 120. The underfill member 105 may prevent a decrease in the bonding reliability of the semiconductor package 20 due to a difference between the coefficients of thermal expansion of the first rewiring 152 and second semiconductor chip 120, and may protect a first connection member 103 from external factors. The underfill member 105 may be an insulation material, such as an epoxy resin, as an example.

In the semiconductor package 20, the second semiconductor chip 120 is disposed on the active surface of the first semiconductor chip 110 in a flip-chip bonding manner or configuration. Accordingly, a path length between the first and second semiconductor chips 110 and 120 is prevented from being increased, and a height of the semiconductor package 20 is reduced, thereby increasing integration of the semiconductor package 20.

FIG. 4 is a cross-sectional view of another embodiment of a semiconductor package 30, according to aspects of the inventive concept. In FIG. 4, the same reference numerals as in FIG. 1 denote the same elements, and details thereof are not repeated.

Referring to FIG. 4, the semiconductor package 30 may include a plurality of second semiconductor chips 120 aligned side-by-side. Active surfaces of the second semiconductor chips 120 are exposed by the second molding member 140, and the second semiconductor chips 120 may be electrically connected to the first semiconductor chip 110 via the first connection member 180, the first rewiring 152, and the pad 112 through the third rewiring 172 formed on the exposed active surfaces.

In FIG. 4, two second semiconductor chips 120 are provided in the second molding member 140, but the number of second semiconductor chips 120 is not limited thereto. Also, the types and sizes of the second semiconductor chips 120 may be the same or different from each other.

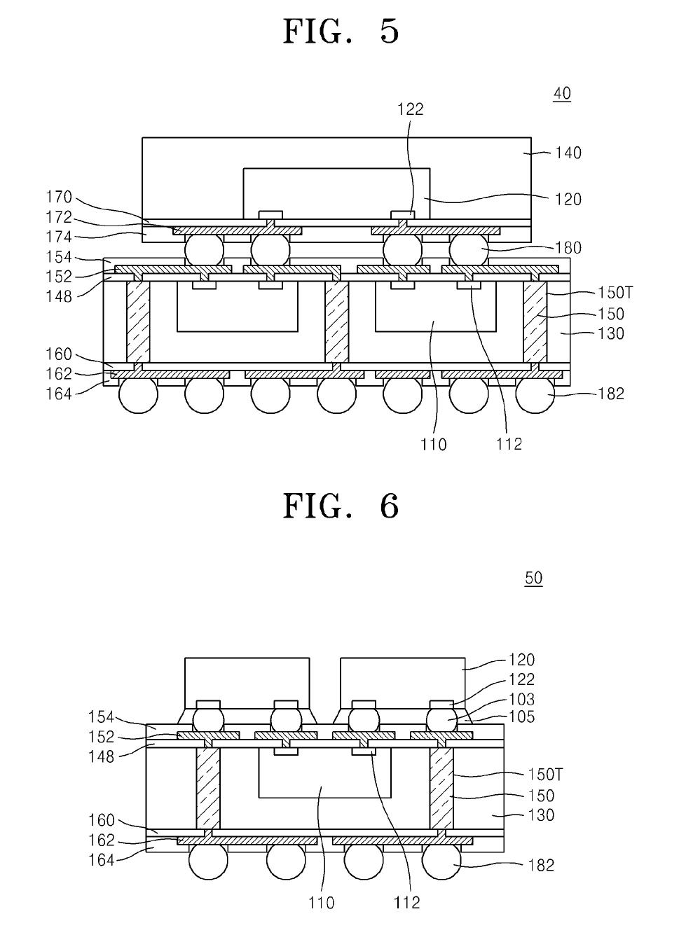

FIG. 5 is a cross-sectional view of another embodiment of a semiconductor package 40 according to aspects of the inventive concept. In FIG. 5, the same reference numerals as in FIG. 1 denote the same elements, and details thereof are not repeated.

Referring to FIG. 5, the semiconductor package 40 may include a plurality of first semiconductor chips 110 aligned side-by-side. Active surfaces of the first semiconductor chips 110 are exposed by the first molding member 130, and the first semiconductor chips 110 may be electrically connected to the second semiconductor chip 120 via the first connection member 180, the third rewiring 172, and the pad 122 through the first rewiring 152 formed on the active surfaces.

In FIG. 5, two first semiconductor chips 110 are provided in the first molding member 130, but the number of first semiconductor chips 110 is not limited thereto. Also, the types and sizes of the first semiconductor chips 110 may be the same or different from each other, in various embodiments.

FIG. 6 is a cross-sectional view of another embodiment of a semiconductor package 50 according to aspects of the inventive concept. In FIG. 6, the same reference numerals as in FIG. 3 denote the same elements, and details thereof are not repeated.

Referring to FIG. 6, the semiconductor package 50 includes a plurality of second semiconductor chips 120 provided on the first rewiring 152 aligned side-by-side. The second semiconductor chips 120 may be disposed on the first rewiring 152 in a flip-chip bonding manner or configuration, so as to face the active surface of the first semiconductor chip 110.

The second semiconductor chip 120 may be electrically connected to the first semiconductor chip 110 through the first connection member 103 and the first rewiring 152.

In FIG. 6, two second semiconductor chips 120 are disposed on the first rewiring 152, but the number of second semiconductor chips 120 is not limited thereto. Also, products and sizes of the second semiconductor chips 120 may be the same or different from each other, in various embodiments.

The underfill member 105 may be disposed between the first rewiring 152 and the second semiconductor chip 120. The underfill member 105 may prevent the bonding reliability of the semiconductor package 50 from decreasing due to a difference between the coefficients of thermal expansion of the first rewiring 152 and second semiconductor chip 120, and may protect the first connection member 103 from external factors.

In the semiconductor package 50, the second semiconductor chips 120 are disposed on the active surface of the first semiconductor chip 110 in a flip-chip bonding manner or configuration. Accordingly, a path length between the first and second semiconductor chips 110 and 120 is prevented from increasing, and a height of the semiconductor package 50 is reduced, thereby increasing the integration of the semiconductor package 50.

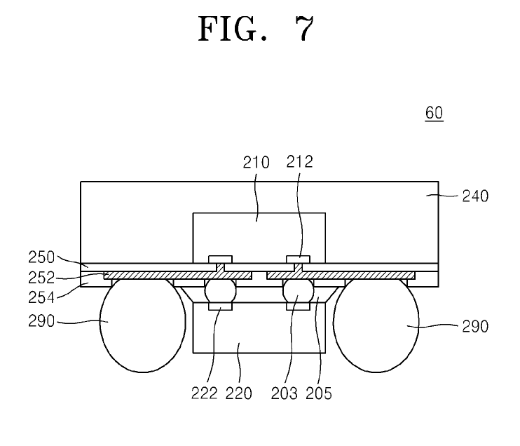

FIG. 7 is a cross-sectional view of another embodiment of a semiconductor package 60, according to aspects of the inventive concept.

Referring to FIG. 7, the semiconductor package 60 includes a first semiconductor chip 210 and a second semiconductor chip 220, respectively, disposed at a top and at a bottom so that active surfaces thereof face each other. The semiconductor package 60 further includes a first molding member 240 for sealing the first semiconductor chip 210 and exposing the active surface of the first semiconductor chip 210 through a bottom surface, a rewiring 252 formed on the bottom surface of the first molding member 240 and the active surface of the first semiconductor chip 210, and a first connection member 203 disposed between the first and second semiconductor chips 210 and 220.

A top surface of the first semiconductor chip 210 is the active surface and a bottom surface of the first semiconductor chip 210 is an inactive surface, in this embodiment. The active surface of the first semiconductor chip 210 includes at least one pad 212 connected to an IC therein.

The first molding member 240 seals the first semiconductor chip 210 and exposes the active surface of the first semiconductor chip 210 through a bottom surface. The active surface of the first semiconductor chip 210 and the bottom surface of the first molding member 240 may be at the same level, in various embodiments.

The rewiring 252 is formed on the active surface of the first semiconductor chip 210 and the bottom surface of the first molding member 240. In other words, an insulation layer 250 exposing the pad 212 of the first semiconductor chip 210, the rewiring 252 electrically connected to the pad 212 on the insulation layer 250, and a solder resist layer 254 exposing a predetermined region of the rewiring 252 on the insulation layer 250 are formed.

The second semiconductor chip 220 is disposed on the rewiring 252 in a flip-chip bonding manner or configuration. The first semiconductor chip 210 may operate as a master chip.

The first connection member 203 is disposed between the rewiring 252 and the active surface of the second semiconductor chip 220. The first connection member 203 may be a bump. The second semiconductor chip 220 may be electrically connected to the first semiconductor chip 210 through the first connection member 203 and the rewiring 252. The second semiconductor chip 220 may operate as a slave chip, and the slave chip may provide read data to the first semiconductor chip 210 by receiving various control signals or record data from the master chip, for example, the first semiconductor chip 210.

An underfill member 205 may be disposed between the rewiring 252 and the second semiconductor chip 220.

The total height of the first connection member 203 and the second semiconductor chip 220 disposed on the rewiring 252 may be lower than a height of a connection member 290 disposed on the rewiring 252. In other words, the semiconductor package 60 is physically and electrically connected to an external device through the connection member 290, and the height of the first connection member 203 may be selected such that the bottom surface, i.e., the inactive surface, of the second semiconductor chip 220 does not contact the external device. Alternatively, the height of the first connection member 203 may be selected such that the bottom surface of the second semiconductor chip 220 contacts the external device. For example, when the semiconductor package 60 is connected to the external device, the height of the first connection member 203 may be selected such that the bottom surface of the second semiconductor chip 220 contacts a heat sink (not shown) provided at the external device.

The connection member 290 electrically connected to the external device is disposed on the rewiring 252, and the connection member 290 may be disposed to surround the second semiconductor chip 220.

The semiconductor package 60 receives an electric signal from the external device through the connection member 290, and the received electric signal is transmitted to the first semiconductor chip 210 through the rewiring 252 and the pad 212. The electric signal transmitted to the first semiconductor chip 210 is transmitted to the second semiconductor chip 220 through the pad 212, the rewiring 252, the first connection member 203, and a pad 222. Since the first and second semiconductor chips 210 and 220 having the facing active surfaces are electrically connected to each other through the first connection member 203, a transmission path may be reduced, thereby improving a speed of the semiconductor package 60.

In the semiconductor package 60, one second semiconductor chip 220 is disposed on the rewiring 252, but alternatively, a plurality of the second semiconductor chips 220 may be disposed.

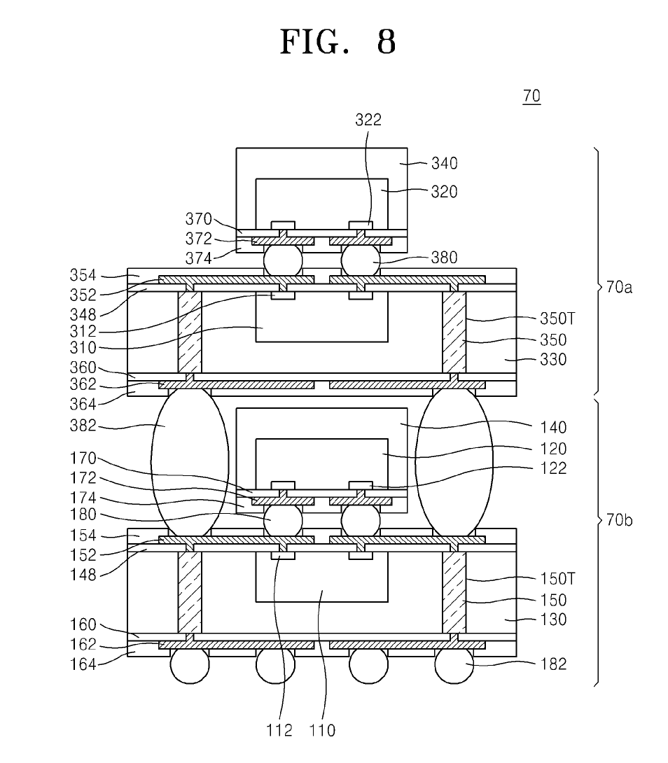

FIG. 8 is a cross-sectional view of another embodiment of a semiconductor package 70 according to aspects of the inventive concept. In FIG. 8, the same reference numerals as in FIG. 1 denote the same elements, and details thereof are not repeated.

Referring to FIG. 8, the semiconductor package 70 includes the semiconductor packages 10 of FIG. 1 stacked on each other.

The semiconductor package 70 includes a third semiconductor chip 310 and a fourth semiconductor chip 320 respectively disposed at a bottom and at a top so that active surfaces thereof face each other; a third connection member 380 electrically connecting the third and fourth semiconductor chips 310 and 320, a third molding member 330 sealing the third semiconductor chip 310 while exposing the active surface of the third semiconductor chip 310 through a top surface; and a fourth molding member 340 sealing the fourth semiconductor chip 320 while exposing the active surface of the fourth semiconductor chip 320 through a bottom surface.

The third semiconductor chip 310 is disposed such that the active surface is a top surface and an inactive surface is a bottom surface. The third semiconductor chip 310 may include an IC therein. The active surface of the third semiconductor chip 310 includes at least one pad 312 connected to the IC.

The third molding member 330 seals the third semiconductor chip 310 while exposing the active surface of the third semiconductor chip 310 through a top surface. The top surface of the third molding member 330 may be at the same level with the active surface of the third semiconductor chip 310. For example, the third molding member 330 may include an insulation resin, such as an epoxy molding compound, as an example.

A through-via 350 is formed through the third molding member 330, and the through-via 350 may be formed by filling a conductive material in a through hole 350T of the third molding member 330.

A fourth rewiring 352 is formed on the active surface of the third semiconductor chip 310, the through-via 350, and the top surface of the third molding member 330. A fifth rewiring 362 is formed on bottom surfaces of the third molding member 330 and through-via 350. The fourth and fifth rewirings 352 and 362 may be electrically connected to each other through the through-via 350.

The fourth rewiring 352 is electrically connected to the third semiconductor chip 310, the pad 312, the through-via 350, and the third connection member 380. The fourth rewiring 352 may include at least one material selected from among Al, Cu, Sn, Ni, Au, Pt, and an alloy thereof, and may be a multilayer in which Cu, Au, and Ni are sequentially stacked.

A fourth connection member 382 electrically connecting an upper semiconductor package 70a to a lower semiconductor package 70b is formed on a bottom surface of the fifth rewiring 362, and the fifth rewiring 362 is electrically connected to the through-via 350 and the fourth connection member 382. The fifth rewiring 362 may include at least one material selected from among Al, Cu, Sn, Ni, Au, Pt, and an alloy thereof, and may be a multilayer in which Cu, Au, and Ni are sequentially stacked.

The fourth semiconductor chip 320 is disposed such that the active surface faces the active surface of the third semiconductor chip 310. In other words, the fourth semiconductor chip 320 is disposed such that the active surface is a bottom surface and an inactive surface is a top surface. The fourth semiconductor chip 320 may include an IC therein. The active surface of the fourth semiconductor chip 320 includes at least one pad 322 connected to the IC. The pad 322 includes at least one material selected from among Al, Cu, Ag, Au, and Pd.

The fourth semiconductor chip 320 may be a memory chip, as an example. The memory chip may include various types of memory circuits, such as DRAM, SRAM, a flash memory, PRAM, ReRAM, FeRAM, and MRAM. The fourth molding member 340 seals the fourth semiconductor chip 320 and exposes the active surface of the fourth semiconductor chip 320 through a bottom surface. The bottom surface of the fourth molding member 230 may be at the same level with the active surface of the fourth semiconductor chip 320. For example, the fourth molding member 230 may include an insulation resin, such as an epoxy molding compound, as an example.

A sixth rewiring 372 is formed on the active surface of the fourth semiconductor chip 320 and the bottom surface of the fourth molding member 340.

The sixth rewiring 372 is electrically connected to the fourth semiconductor chip 320, the pad 322, and the third connection member 380. The sixth rewiring 372 may include at least one material selected from among Al, Cu, Sn, Ni, Au, Pt, and an alloy thereof, and may be a multilayer in which Cu, Au, and Ni are sequentially stacked.

The semiconductor package 70 according to the current embodiment is electrically connected to an external device through the second connection member 182, and a signal transmitted and received through the second connection member 182 may be transmitted and received with the third semiconductor chip 310 through the second rewiring 162, the through-via 150, the first rewiring 152, the fourth connection member 382, the fifth rewiring 362, the through-via 350, the fourth rewiring 352, and the pad 312. The third semiconductor chip 310 may transmit and receive a signal with the fourth semiconductor chip 320 through the fourth rewiring 352, the third connection member 380, the sixth rewiring 372, and the pad 322.

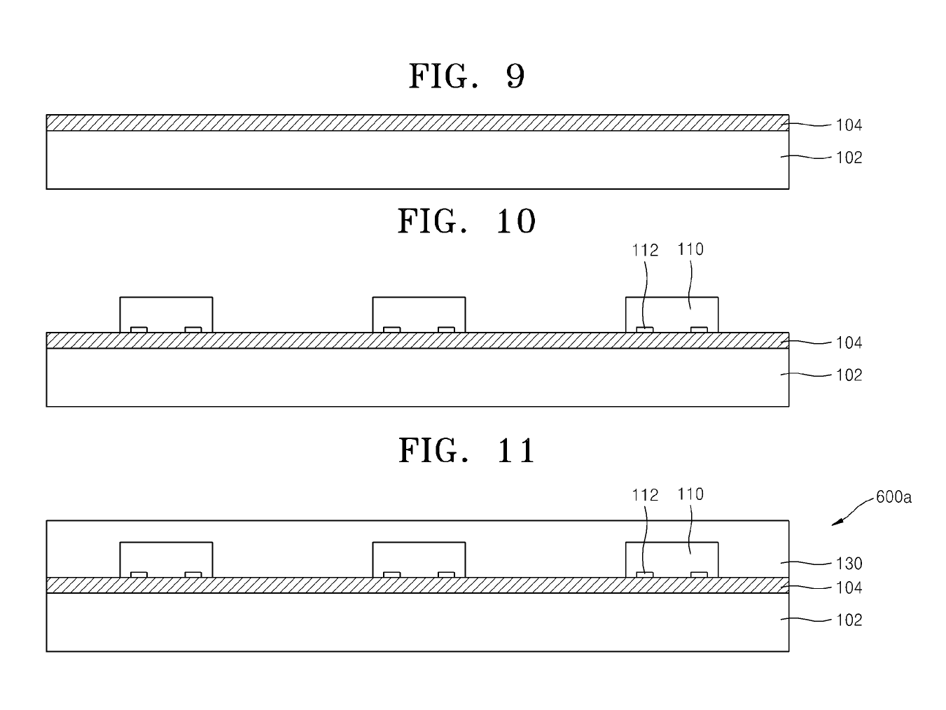

FIGS. 9 through 19 are cross-sectional views of an embodiment of a method of manufacturing a semiconductor package, according to an embodiment of the inventive concept.

Referring to the embodiment of FIG. 9, a carrier 102 is prepared, and an adhesive member 104 is formed on the carrier 102.

The carrier 102 performs functions of a supporter of a semiconductor chip when a first molded wafer 600a of FIG. 11 is formed, and the carrier 102 may be formed of a material containing stainless steel or organic resin material, as examples, but the method is not limited thereto.

The adhesive member 104 may be formed of a material that enables the semiconductor chip to have an adhesive state during following operations, and is easily separated from the carrier 102 after operations. Accordingly, the adhesive member 104 may be formed of a material having adhesive strength that deteriorates via a thermal process or ultraviolet (UV) irradiation. The adhesive member 104 may have a tape or thin-film shape or form. The adhesive member 104 may be a thermoplastic resin and UV-sensitive resin, as examples, but is not limited thereto.

Referring to the embodiment of FIG. 10, the plurality of first semiconductor chips 110 are disposed on the adhesive member 104. Here, the first semiconductor chip 110 is disposed on the adhesive member 104 such that the active surface on which the pad 112 is formed faces downward.

The first semiconductor chip 110 may include the IC therein, and the active surface of the first semiconductor chip 110 includes at least one pad 112 connected to the IC. The first semiconductor chip 110 may be a memory chip, and the memory chip may include various types of memory circuits, such as DRAM, SRAM, a flash memory, PRAM, ReRAM, FeRAM, and MRAM.

Referring to the embodiment of FIG. 11, the first molding member 130 is formed on the adhesive member 104 to cover the adhesive member 104 and the first semiconductor chip 110.

The first molding member 130 is an encapsulation material, and thus fixes the plurality of first semiconductor chips 110 and functions as an insulator that insulates the first semiconductor chips 110 from each other. The first molding member 130 may include an insulation resin, for example, an epoxy molding compound, as an example.

By forming the first molding member 130, the first molded wafer 600a in which the plurality of first semiconductor chips 110 are spaced apart from each other by a predetermined interval may be formed.

Referring to the embodiment of FIG. 12, the adhesive strength of the adhesive member 104 to the first molded wafer 600a is deteriorated when the adhesive member 104 is thermally processed via UV irradiation. Accordingly, the first molded wafer 600a is easily separated from the adhesive member 104.

The first molded wafer 600a may have a structure wherein the active surface of the first semiconductor chip 110 is externally exposed and the inactive surface is covered by the first molding member 130. Also, in the first molded wafer 600a, the top surface of the first molding member 130 and the active surface of the first semiconductor chip 110 may be on the same level.

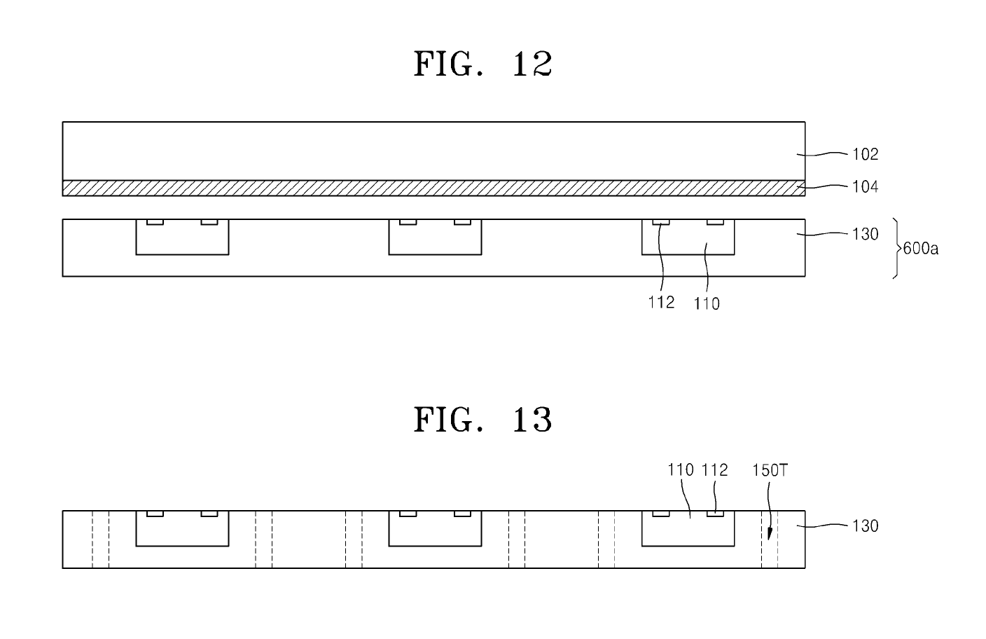

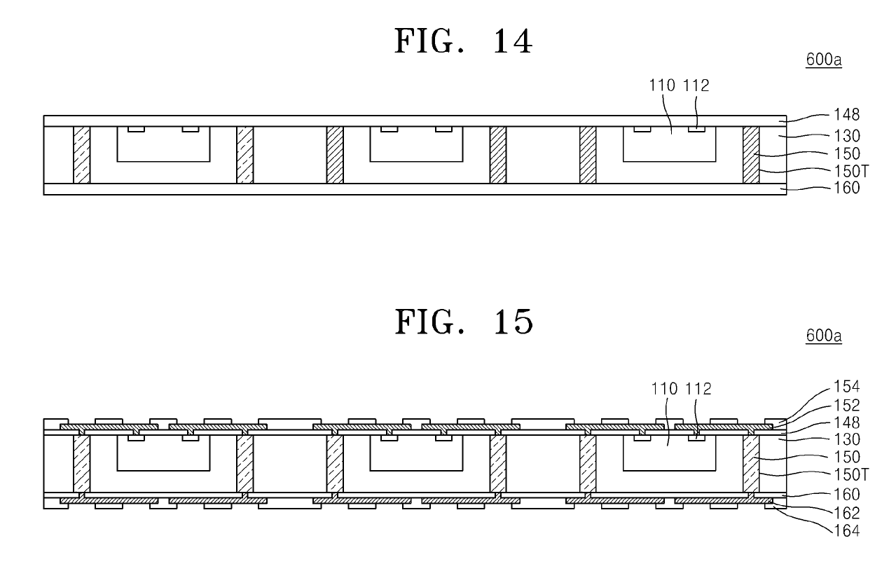

Referring to the embodiment of FIG. 13, a plurality of through holes 150T for forming through-vias are formed in the first molding member 130 between the first semiconductor chips 110.

The through hole 150T may be formed via a laser or dry-etching method, as examples but the method is not limited thereto.

Referring to the embodiment of FIG. 14, the through-via 150 is formed by filling a conductive material into the through hole 150T. The through-via 150 may be formed via an electroplating, printing, or dispensing operation, as examples, but the method is not limited thereto.

The first insulation layer 148 is formed on the active surface of the first semiconductor chip 110, the through-via 150, and the top surface of the first molding member 130. The second insulation layer 160 is formed on the bottom surfaces of the first molding member 130 and through-via 150.

The first and second insulation layers 148 and 160 may be formed of a material commonly used in the related art, and may be a photosensitive polyimide. Alternatively, the first and second insulation layers 148 and 160 may be formed of a thermally conductive low dielectric material.

Referring to the embodiment of FIG. 15, a pattern for exposing the pad 112 of the first semiconductor chip 110 is formed on the first insulation layer 148 via a photolithography process using a mask, and a pattern for exposing a bottom surface of the through-via 150 is formed on the second insulation layer 160.

The first rewiring 152 electrically connected to the pad 112 is formed on the first insulation layer 148, and the second rewiring 162 electrically connected to the through-via 150 is formed on the second insulation layer 160. The first and second rewirings 152 and 162 may be formed by any of a variety of processes, such as by forming a conductive film, coating a photoresist film, and by performing exposure, developing, and etching processes. Alternatively, patterns of the first and second rewirings 152 and 162 may be initially formed via a screen printing process.

The first and second solder resist layers 154 and 164 are formed on the first and second insulation layers 148 and 160 to cover the first and second rewirings 152 and 162.

Exposure and developing processes are performed on the first and second solder resist layers 154 and 164 to expose predetermined regions of the first and second rewirings 152 and 162. The first and second rewirings 152 and 162 may be electrically connected to each other via the through-via 150 penetrating through the first molding member 130.

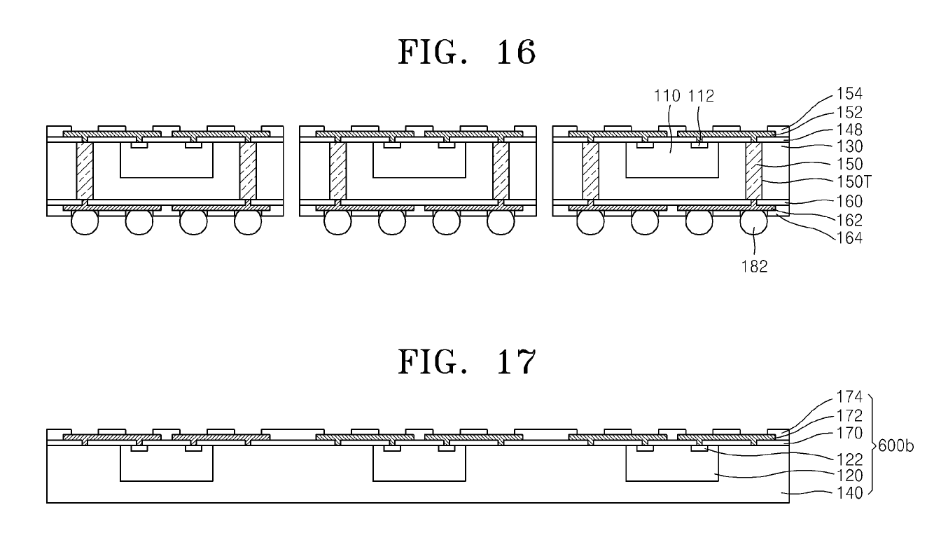

Referring to the embodiment of FIG. 16, the second connection member 182 for an electric connection with the external device is formed on the second rewiring 162.

By performing a singulation process, the first molded wafer 600a is divided into semiconductor packages, each including one first semiconductor chip 110. However, alternatively, the first molded wafer 600a may be divided into semiconductor packages each including the plurality of first semiconductor chips 110.

Referring to the embodiment of FIG. 17, according to a series of operations as described above with reference to FIGS. 9 through 12, a second molded wafer 600b wherein the active surface of the second semiconductor chip 120 is exposed and the inactive surface of the second semiconductor chip 120 is covered by the second molding member 140 is formed.

The third insulation layer 170 is formed on the active surface of the second semiconductor chip 120 and the top surface of the second molding member 140.

A pattern for exposing the pad 122 of the second semiconductor chip 120 is formed on the third insulation layer 170 via a photolithography process using a mask, in this embodiment.

The third rewiring 172 electrically connected to the pad 122 is formed on the third insulation layer 170.

A predetermined region of the third rewiring 172 is exposed, and the third solder resist layer 174 is formed on the third insulation layer 170 and the third rewiring 172.

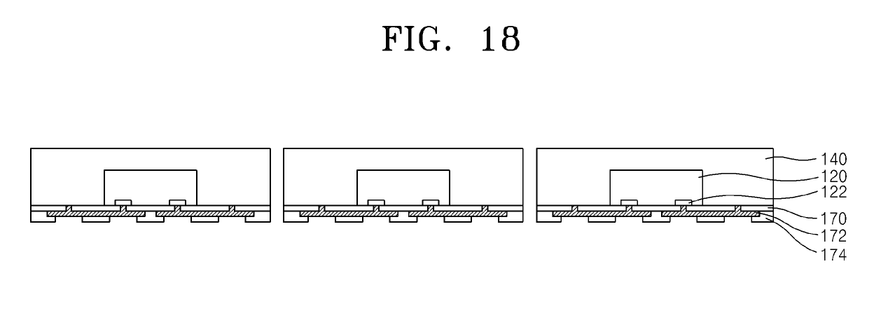

Referring to the embodiment of FIG. 18, the second molded wafer 600b is divided into semiconductor packages, each including one second semiconductor chip 120 by performing a singulation process. Alternatively, the second molded wafer 600b may be divided into semiconductor packages, each including the plurality of second semiconductor chips 120.

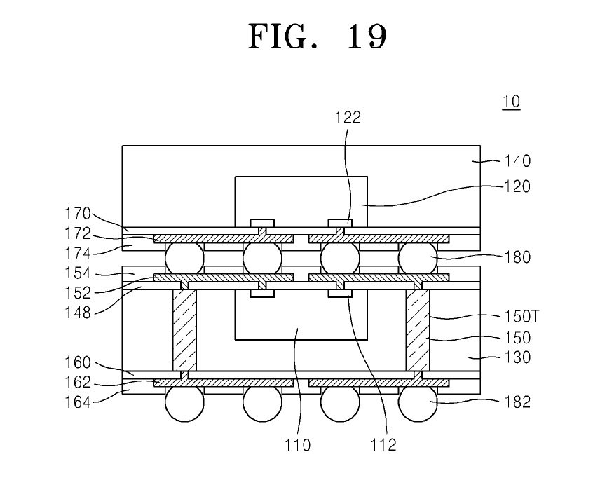

Referring to the embodiment of FIG. 19, the first connection member 180 is disposed between the second and third rewirings 162 and 172 for an electric connection between the first and second semiconductor chips 110 and 120, thereby forming the semiconductor package 10.

The semiconductor package 10 is capable of wireless stacking by using a fan-out wafer level package, and different types of chip and the same types of chips may be stacked. Also, since the semiconductor package 10 has a master chip/slave chip structure having a face-to-face structure wherein the active surfaces of the first and second semiconductor chips 110 and 120 face each other, loading of the semiconductor package 10 may be reduced and a speed of the semiconductor package 10 may be improved. Also, the semiconductor package 10 is formed by using a wafer-level package, but alternatively, a panel-level package may be used in other embodiments.

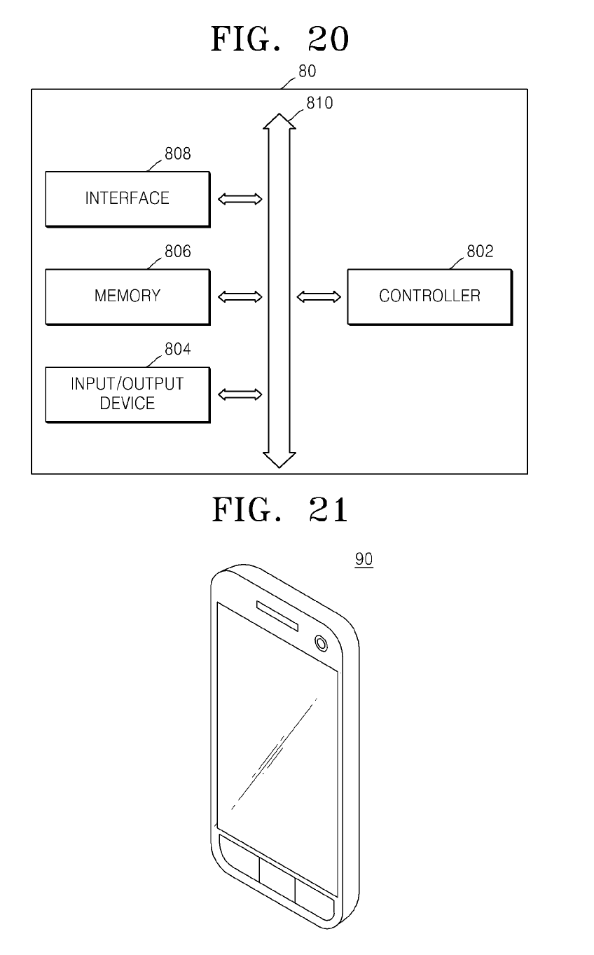

FIG. 20 is a schematic diagram of an embodiment of a system 80 comprising a semiconductor package according to aspects of the inventive concept. However, the semiconductor package may faun part of any number of systems or devices.

Referring to the embodiment of FIG. 20, the system 80 may include a controller 802, an input/output device 804, a memory 806, and an interface 808. The system 80 may be a mobile system or a system for transmitting or receiving information. The mobile system may be a personal digital assistant (PDA), a portable computer, a web tablet, a wireless phone, a mobile phone, a digital music player, or a memory card, as examples.

The controller 802 may execute a program and control the system 80. The controller 802 may be a microprocessor, a digital signal processor, a micro controller, or a device similar thereto.

The input/output device 804 may be used to input or output data of the system 80. The system 80 may exchange data with an external device, for example, a personal computer or a network, by being connected to the external device through the input/output device 804. The input/output device 804 may be a keypad, a keyboard, or a display, as examples.

The memory 806 may store code and/or data for an operation of the controller 802 and/or store data processed by the controller 802. The memory 806 may include an embodiment of a semiconductor package according to aspects of the inventive concept.

The interface 808 may be a data transmission path between the system 80 and another external device. The controller 802, the input/output device 804, the memory 806, and the interface 808 may communicate with each other through a bus 810. For example, the system 80 may be used for a solid state disk (SSD) or household appliances.

FIG. 21 is a perspective view of an embodiment of an electronic device including a semiconductor package manufactured according to aspects of the inventive concept.

Referring to FIG. 21, the system 80 of FIG. 20 may be included in or as a mobile phone 90. Alternatively, the system 80 of FIG. 20 may be included in or as a portable laptop, an MP3 player, a navigation, an SSD, a vehicle, or household appliances, as examples.

While exemplary embodiment in accordance with the inventive concept have been particularly shown and described with reference to the figures, it will be understood that various changes in form and details may be made therein without departing from the spirit and scope of the inventive concept, as provided in the following claims.

What is claimed is:

1. A semiconductor package comprising:
a first semiconductor chip and a second semiconductor chip respectively disposed at a bottom and at a top so that active surfaces thereof face each other;
a first molding member for sealing the first semiconductor chip and exposing the active surface of the first semiconductor chip through a top surface;
a first rewiring formed on the top surface of the first molding member and the active surface of the first semiconductor chip;
a second rewiring formed on a bottom surface of the first molding member;
a through-via penetrating through the first molding member and electrically connecting the first and second rewirings; and
a first connection member disposed between the first and second semiconductor chips.

2. The semiconductor package of claim 1, wherein the top surface of the first molding member and the active surface of the first semiconductor chip are at the same level.

3. The semiconductor package of claim 1, further comprising a second connection member formed on the second rewiring to be electrically connected to an external device.

4. The semiconductor package of claim 1, wherein the first semiconductor chip is a master chip and the second semiconductor chip is a slave chip.

5. The semiconductor package of claim 1, further comprising a second molding member for sealing the second semiconductor chip and exposing the active surface of the second semiconductor chip.

6. The semiconductor package of claim 5, wherein a bottom surface of the second molding member and the active surface of the second semiconductor chip are at the same level.

7. The semiconductor package of claim 5, further comprising a third rewiring formed on a bottom surface of the second molding member and the active surface of the second semiconductor chip.

8. The semiconductor package of claim 7, wherein the first connection member electrically connects the first and third rewirings.

9. The semiconductor package of claim 1, wherein the through-via is spaced apart from the first semiconductor chip.

10. The semiconductor package of claim 1, wherein the first connection member is disposed between the active surface of the second semiconductor chip and the first rewiring.

11. The semiconductor package of claim 10, further comprising an underfill member formed between the first rewiring and the active surface of the second semiconductor chip.

12. A semiconductor package comprising:
a first semiconductor chip and a second semiconductor chip respectively disposed at a top and at a bottom so that active surfaces thereof face each other;
a first molding member for sealing the first semiconductor chip and exposing the active surface of the first semiconductor chip through a bottom surface;
a rewiring formed on the bottom surface of the first molding member and the active surface of the first semiconductor chip; and
a first connection member disposed between the first and second semiconductor chips.

13. The semiconductor package of claim 12, wherein the active surface of the first semiconductor chip and the bottom surface of the first molding member are at the same level.

14. The semiconductor package of claim 12, further comprising a second connection member formed on the rewiring to be electrically connected to an external device, wherein the second connection member is disposed to surround the second semiconductor chip.

15. The semiconductor package of claim 12, wherein the first connection member is disposed between the rewiring and the active surface of the second semiconductor chip.

16. An electronic system, comprising:
a controller comprising a processor to control the system;
an interface configured as a data transmission path between the system and an external device; and
a semiconductor package including a memory, the semiconductor package comprising:
a first semiconductor chip and a second semiconductor chip respectively disposed at a top and at a bottom so that active surfaces thereof face each other;
a first molding member for sealing the first semiconductor chip and exposing the active surface of the first semiconductor chip through a bottom surface;
a rewiring formed on the bottom surface of the first molding member and the active surface of the first semiconductor chip; and
a first connection member disposed between the first and second semiconductor chips.

17. The system of claim 16, further comprising:
an input/output device configured to exchange data with a user.

18. The system of claim 16, wherein the system includes a cellular telephone.

19. The system of claim 16, wherein the active surface of the first semiconductor chip and the bottom surface of the first molding member are at the same level.

20. The system of claim 16, the semiconductor package further comprising:
a second connection member formed on the rewiring to be electrically connected to the external device, wherein the second connection member is disposed to surround the second semiconductor chip.
